(19) United States
(12) Patent Application Publication
(10) Pub. No.: US 2025/0294856 A1
(43) Pub. Date: Sep. 18, 2025

(54) STACKED TRANSISTORS AND METHOD OF FORMING THE SAME

(71) Applicant: TAIWAN SEMICONDUCTOR MANUFACTURING COMPANY, LTD., Hsinchu (TW)

(72) Inventor: Chih-Yang CHEN, Hsinchu City (TW)

(73) Assignee: TAIWAN SEMICONDUCTOR MANUFACTURING COMPANY, LTD., Hsinchu (TW)

(21) Appl. No.: 18/602,854

(22) Filed: Mar. 12, 2024

(51) Int. Cl. H01L 21/8234; H01L 29/06; H01L 29/08; H01L 29/423; H01L 29/66; H01L 29/775; H01L 29/786

(52) U.S. Cl. CPC H10D 84/013; H10D 30/014; H10D 30/43; H10D 30/6735; H10D 30/6757; H10D 62/115; H10D 62/118; H10D 62/151; H10D 64/017; H10D 64/018; H10D 84/0128; H10D 84/038

(57) ABSTRACT

A device includes a first transistor and a second transistor over the first transistor. The first transistor comprises a plurality of first channel layers arranged one above another, a first gate structure wrapping around each of the plurality of first channel layers, and first source/drain regions on opposite sides of the first gate structure. The second transistor comprises a plurality of second channel layers arranged one above another, a second gate structure wrapping around each of the plurality of second channel layers, and second source/drain regions on opposite sides of the second gate structure. A distance between the first channel layers is different from a distance between the second channel layers.

### BACKGROUND

The semiconductor industry continues to improve the integration density of various electronic components (e.g., transistors, diodes, resistors, capacitors, etc.) by continual reductions in minimum feature size, which allow more components to be integrated into a given area.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an example CFET structure in accordance with some embodiments of the present disclosure.

FIGS. 2A, 3A, 4A, 5A, 6A, 7A, 8A, and 9A are example cross-sectional views of intermediate stages in the CFET manufacturing process, taken along reference cross-section A-A illustrated in FIG. 1 that extends in a direction of current flow between source/drain regions, in accordance with some embodiments of the present disclosure.

FIGS. 2B, 3B, 4B, 5B, 6B, 7B, 8B, and 9B are example cross-sectional views of intermediate stages in the CFET manufacturing process, taken along reference cross-section B-B illustrated in FIG. 1 that extends through a gate region along a longitudinal axis of the gate region, in accordance with some embodiments of the present disclosure.

FIGS. 10-14 illustrate cross-sectional views of various CFET structures in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

As scales of the fin width in fin field effect transistors (FinFET) decreases, channel width variations might cause mobility loss. GAA transistors, such as nanosheet transistors are being studied as an alternative to fin field effect transistors. In a GAA transistor, the gate of the transistor is made all around the channel (e.g., a nanosheet channel or a nanowire channel) such that the channel is surrounded or encapsulated by the gate. Such a transistor has the advantage of improving the electrostatic control of the channel by the gate, which also mitigates leakage currents. Stacked transistor structures, such as complementary field effect transistors (CFETs) including vertically stacked p-type FETs and n-type FETs, can provide further reduced footprint and density improvement for advanced IC technology nodes (particularly as IC technology nodes advance to 3 nm (N3) and below).

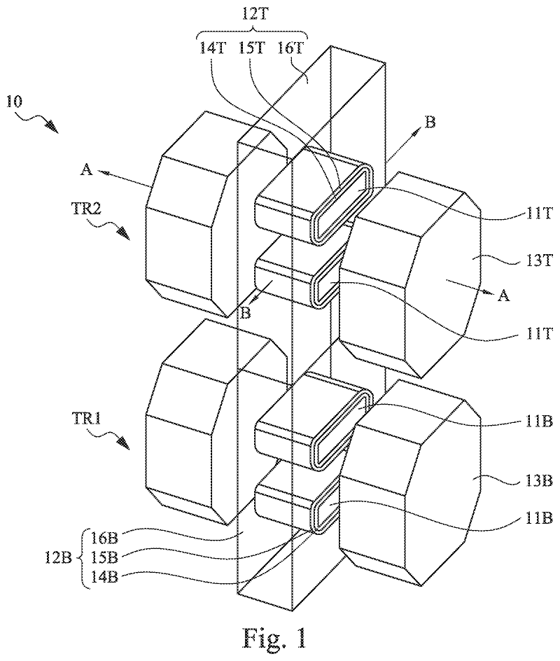

FIG. 1 is a perspective view of an example CFET structure in accordance with some embodiments of the present disclosure. In some embodiments of the present disclosure, a CFET structure 10 includes a first transistor TR1 and a second transistor TR2 vertically stacked over the first transistor TR1, and thus the second transistor TR2 can be interchangeably referred to as a top transistor and the first transistor TR1 can be interchangeably referred to as a bottom transistor. In some embodiments, the first transistor TR1 and the second transistor TR2 are GAA FET transistors. The first transistor TR1 includes first semiconductor channel layers 11B disposed one above another, a first gate structure 12B wrapping around each of the first semiconductor channel layers 11B, and first source/drain epitaxy structures 13B on opposite sides of each of the first semiconductor channel layers 11B. The second transistor TR2 includes second semiconductor channel layers 11T vertically stacked one above another, a second metal gate structure 12T wrapping around each of the second semiconductor channel layers 11T, and second source/drain epitaxy structures 13T on opposite sides of each of the second semiconductor channel layers 11T. The first gate structure 12B may include an interfacial layer 14B, a high-k gate dielectric layer 15B around the interfacial layer, and one or more gate metal layers 16B around the high-k gate dielectric layer 15B. The second gate structure 12T may include an interfacial layer 14T, a gate dielectric layer 15T, and a one or more gate metal layers 16T. In some embodiments, the second gate structure 12T can be electrically isolated from first gate structure 12B by dielectric bonding materials (not shown), as will be described in greater detail below. In some embodiments, the first transistor TR1 is of a first conductivity type (e.g., n-type) and the second transistor TR2 is of a second conductivity type (e.g., p-type) different from the first conductivity type.

FIG. 1 further illustrates reference cross-sections that are used in later figures. Cross-section A-A is parallel to a direction of current flow between the source/drain epitaxy structures 13B of the bottom transistor TR1 and the direction of current flow between the source/drain epitaxy structures 13T of the top transistor TR2. Cross-section B-B is along a longitudinal axis of gate structures 12B, 12T and in a direction, for example, perpendicular to the direction of current flow between the source/drain epitaxy structures 13B of the bottom transistor TR1 and the direction of current flow between the source/drain epitaxy structures 13T of the top transistor TR2. Subsequent figures refer to these reference cross-sections for clarity.

Embodiments of the present disclosure provide various advancements in stacked CFET (complementary field-effect transistor) nanosheet devices. In existing devices, both NFET (n-type field-effect transistor) and PFET (p-type field-effect transistor) possess the same spacing between their respective sheets. However, the embodiments of the present disclosure provide an improved CFET device design where the NFET and PFET have varied spacing between their sheets, which in turn enhances the device's capability for better metal gate work function metal (MG WFM) tuning and more precise threshold voltage (Vt) control.

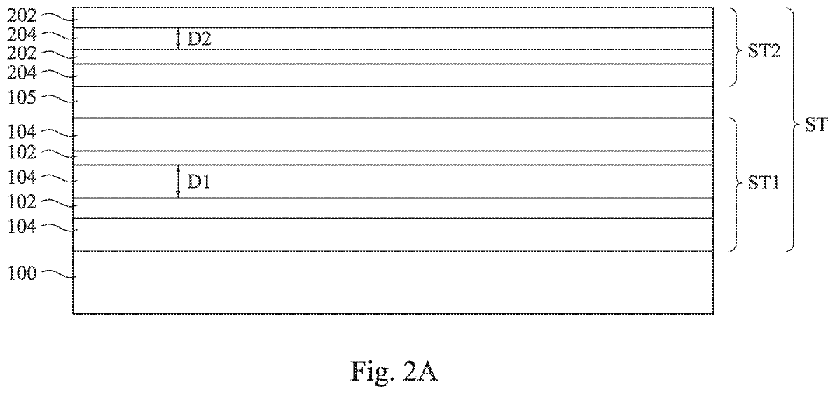

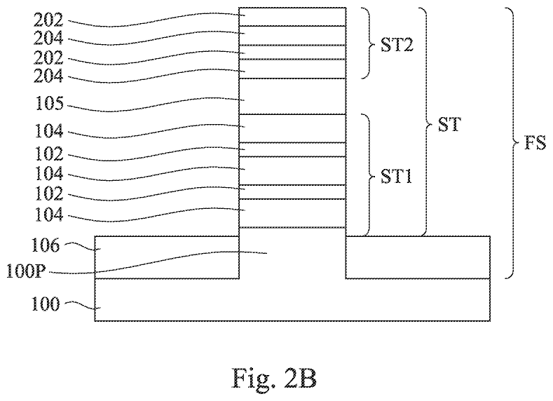

FIGS. 2A through 9B are example cross-sectional views of intermediate stages in the manufacturing of a CFET structure, in accordance with some embodiments. FIGS. 2A, 3A, 4A, 5A, 6A, 7A, 8A, and 9A illustrate reference cross-section A-A illustrated in FIG. 1 that extends in a direction of current flow between source/drain regions. FIGS. 2B, 3B, 4B, 5B, 6B, 7B, 8B, and 9B illustrate reference cross-section B-B illustrated in FIG. 1 that extends through a gate region along a longitudinal axis of the gate region.

In FIGS. 2A and 2B, a substrate 100 is provided. The substrate 100 may be a semiconductor substrate, such as a bulk semiconductor, a semiconductor-on-insulator (SOI) substrate, or the like, which may be doped (e.g., with a p-type or an n-type dopant) or undoped. The substrate 100 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 100 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A semiconductor multilayer stack ST is formed over the substrate 100. The semiconductor multilayer stack ST includes a bottom stack ST1 of alternating semiconductor layers 102 and 104, a semiconductor layer 105 disposed over the bottom stack ST1, and a top stack ST2 of alternating semiconductor layers 202 and 204 over the semiconductor layer 105. The bottom stack ST1 includes alternating layers of first semiconductor layers 104 formed of a first semiconductor material and second semiconductor layers 102 formed of a second semiconductor material. For purposes of illustration and as discussed in greater detail below, the first semiconductor layers 104 will be removed and the second semiconductor layers 102 will be patterned to form channel regions of bottom GAA-FETs. The second semiconductor layers 102 can be interchangeably referred to as bottom channel layers. The top stack ST2 includes alternating layers of first semiconductor layers 204 and second semiconductor layers 202. For purposes of illustration and as discussed in greater detail below, the first semiconductor layers 204 will be removed and the second semiconductor layers 202 will be patterned to form channel regions of top GAA-FETs. The second semiconductor layers 202 can be interchangeably referred to as top channel layers. Each of the layers 102, 104, 105, 202 and 204 may be epitaxially grown using a process such as chemical vapor deposition (CVD), atomic layer deposition (ALD), vapor phase epitaxy (VPE), molecular beam epitaxy (MBE), or the like.

The first semiconductor materials and the second semiconductor materials may be materials having a high-etch selectivity to one another. As such, the first semiconductor layers 104, 204 formed of the first semiconductor material can be removed without significantly removing the second semiconductor layers 102, 202 of the second semiconductor material, thereby allowing the second semiconductor layers 102, 202 to serve as channel regions of bottom GAA-FETs and top GAA-FETs, respectively. The material of the semiconductor layer 105 has a high-etch selectivity to the first and second semiconductor materials. As such, the semiconductor layer 105 can be removed without significantly removing the first semiconductor layers 104, 204 and the second semiconductor layers 102, 202.

In some embodiments, the second semiconductor layers 102 and 202 may be made of pure silicon layers that are free of germanium. The second semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 40 percent and about 60 percent, and the germanium percentage (atomic percentage concentration) of the first semiconductor layers 104 and 204 is in a range from about 20 percent and about 50 percent.

In some embodiments, the first semiconductor layers 104 within the bottom stack ST1 has a thickness different from a thickness of the first semiconductor layers 104 within the top stack ST2, which allows the distance D1 between the second semiconductor layers 102 in the bottom stack ST1 being different from the distance D2 between the second semiconductor layers 202 in the top stack ST2, thereby improving the capability for better metal gate work function metal (MG WFM) tuning and more precise threshold voltage (Vt) control for the bottom GAA-FETs and top GAA-FETs. In the embodiments as illustrated in FIGS. 2A and 2B, the distance D1 between the second semiconductor layers 102 in the bottom stack ST1 is greater than the distance D2 between the second semiconductor layers 202 in the top stack ST2, which allows for forming more work function metal layers or thicker work function metal layers in bottom GAA-FETs than in top GAA-FETs.

A patterning process may be performed to the semiconductor stack ST and the substrate 100 to form a fin structure FS, as shown in FIG. 2B. In some embodiments, the patterning process may include forming a patterned photoresist layer over the stack ST, and then performing an etching process to remove unwanted portions of the semiconductor stack ST and the substrate 100 exposed by the patterned photoresist layer. The fin structure may include a remaining portion of the semiconductor stack ST and a semiconductor strip 100P protruding over the substrate 100. In some embodiments, the etching process may include wet etch, dry etch, or the like.

The fin structure FS may be patterned by any suitable method. For example, the fin structure FS may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structure FS. While each of the fin structure FS are illustrated as having a consistent width throughout, in other embodiments, the fin structure FS may have tapered sidewalls such that a width of each of the fin structure FS continuously increases in a direction towards the substrate 100.

After the fin structure is formed, isolation structures 106 are formed over the substrate 100 and laterally surround the fin structure FS. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof.

The isolation structures 106 may be formed by depositing an insulation material over the fin structure FS. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers fin structure. Although the insulation material is illustrated as a single layer, some embodiments may utilize multiple layers. For example, in some embodiments a liner (not separately illustrated) may first be formed along surfaces of the fin structure FS. Thereafter, a fill material, such as those discussed above may be formed over the liner.

A removal process is then applied to the insulation material to remove excess insulation material over the fin structure. In some embodiments, a planarization process such as a chemical mechanical polish (CMP), an etch-back process, combinations thereof, or the like may be utilized. The planarization process exposes the topmost semiconductor layer 204 such that top surface of the topmost semiconductor layer 204 and the insulation material are level after the planarization process is complete.

The insulation material is then recessed to form the isolation structures 106. The insulation material is recessed such that upper portions of fin structure FS protrude from between neighboring isolation structures 106. Further, the top surfaces of the isolation structures 106 may have a flat surface as illustrated, a convex surface, a concave surface (such as dishing), or a combination thereof. The top surfaces of the isolation structures 106 may be formed flat, convex, and/or concave by an appropriate etch. The isolation structures 106 may be recessed using an acceptable etching process, such as one that is selective to the material of the insulation material (e.g., etches the material of the insulation material at a faster rate than the material of the fin structure FS. For example, an oxide removal using, for example, dilute hydrofluoric (dHF) acid may be used.

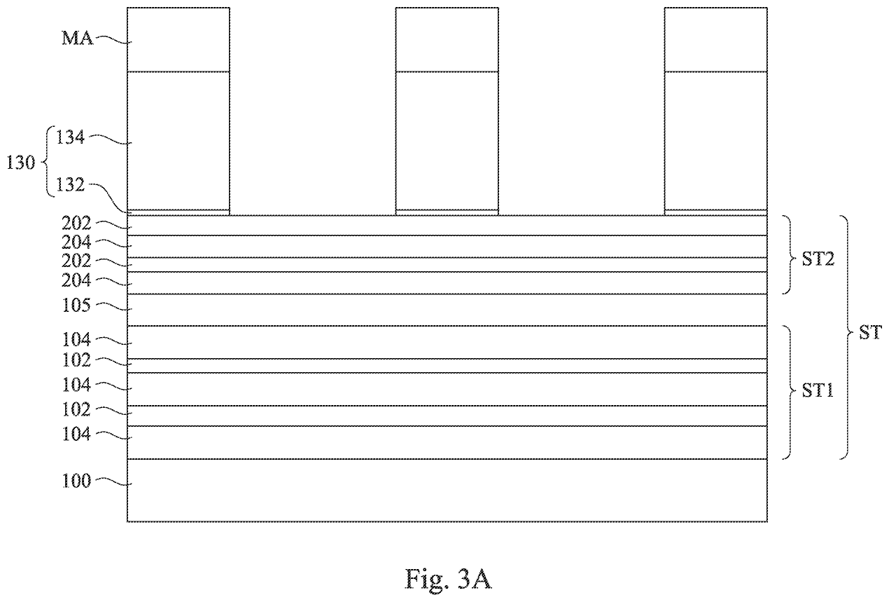

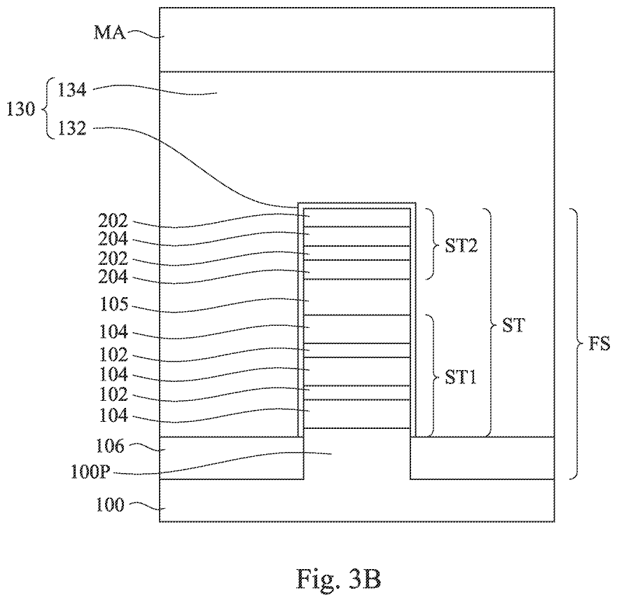

In FIGS. 3A and 3B, dummy gate structures 130 are formed over the substrate 100 and crossing the fin structure. In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA over the dummy gate layer, and then performing an etching process to the dummy dielectric layer and the dummy gate layer by using the patterned masks MA as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation. In some embodiments, the patterned masks MA include dielectric material such as silicon nitride or silicon oxide.

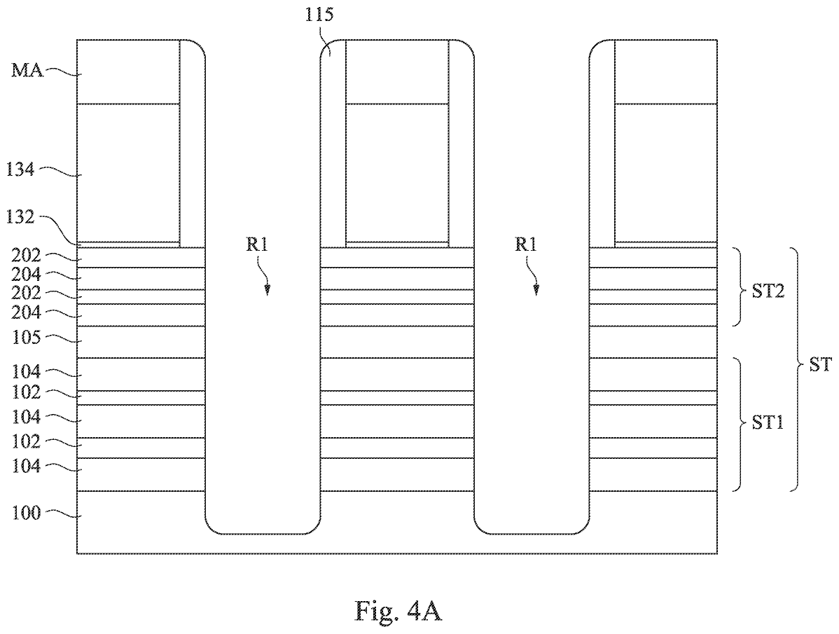

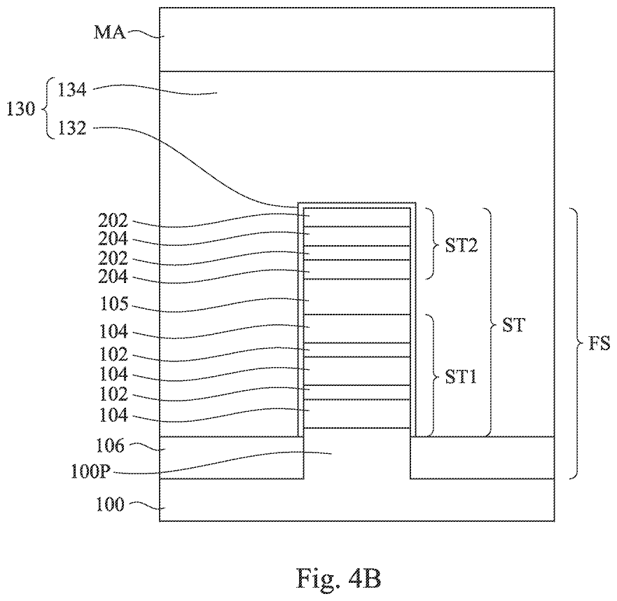

In FIGS. 4A and 4B, gate spacers 115 are formed on opposite sidewalls of each of the dummy gate structures 130. In some embodiments, the gate spacers 115 may be formed of silicon oxide, silicon nitride, silicon oxynitride, combinations thereof. In some embodiments, the gate spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130. In some embodiments, the remaining vertical portions of the spacer layer on sidewalls of the dummy gate structures 130 can be referred to as gate spacers 115. In some embodiments, the spacer layer may be deposited using techniques such CVD, ALD, or the like.

In FIGS. 4A and 4B, source/drain recesses R1 are formed in fin structure FS. Epitaxial source/drain regions will be subsequently formed in the source/drain recesses R1. The source/drain recesses R1 may extend through the semiconductor multilayer stack ST and into the substrate 100. The source/drain recesses R1 may be formed by etching the semiconductor multilayer stack ST and the substrate 100 using anisotropic etching processes, such as RIE, NBE, or the like. The gate spacers 115 and pattered masks MA mask portions of the semiconductor multilayer stack ST during the etching processes used to form the source/drain recesses R1. A single etch process or multiple etch processes may be used to etch each layer of the semiconductor multilayer stack ST. Timed etch processes may be used to stop the etching of the source/drain recesses R1 after the source/drain recesses R1 reach a target depth.

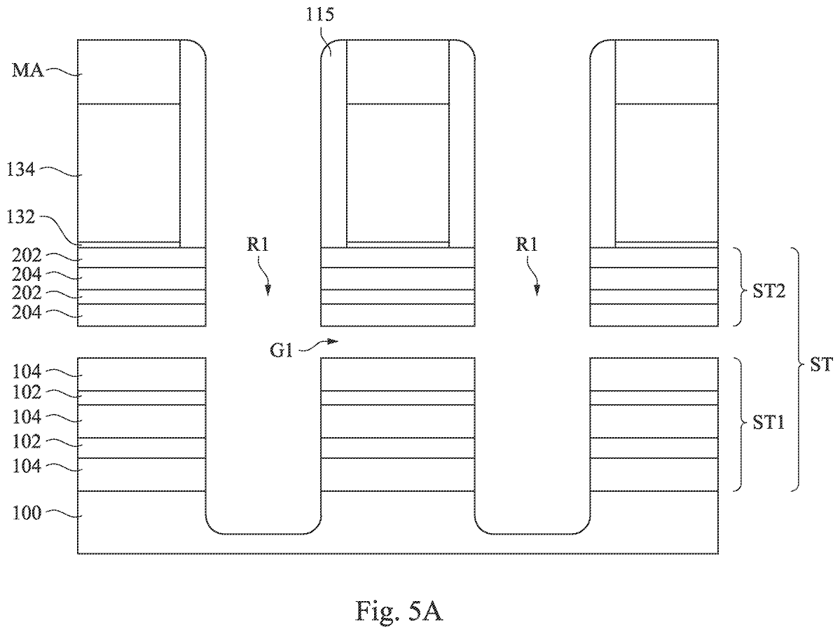

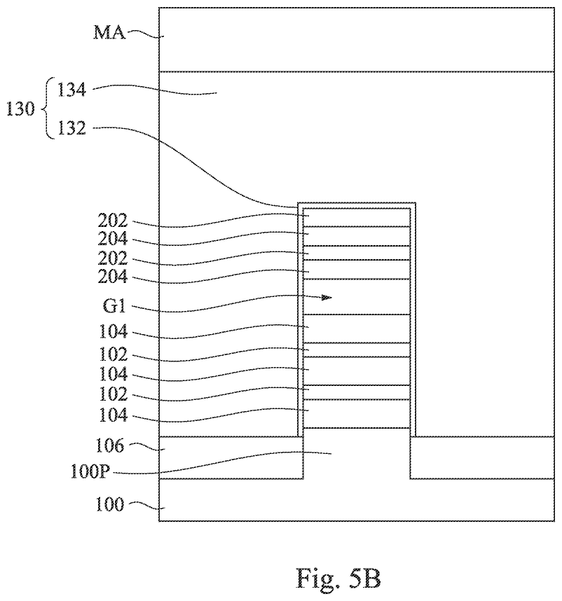

In FIGS. 5A and 5B, an etching process is performed to remove the semiconductor layer 105 exposed by the source/drain recesses R1. As a result, gaps G1 may be formed between the bottom stack ST1 and the top stack ST2. In greater detail, each of the gaps G1 is vertically between the topmost semiconductor layer 104 and the bottommost semiconductor layer 202. In some embodiments, because the semiconductor layer 105 has greater germanium concentration than the semiconductor layers 102, 104, 202, and 204, the semiconductor layer 105 can be removed by using a selective etching process that etches the high-germanium materials of the semiconductor layer 105 at a much faster etch rate than etching the materials of the semiconductor layers. Therefore, the semiconductor layers 102, 104, 202, and 204 may keep substantially intact in the selective etching process.

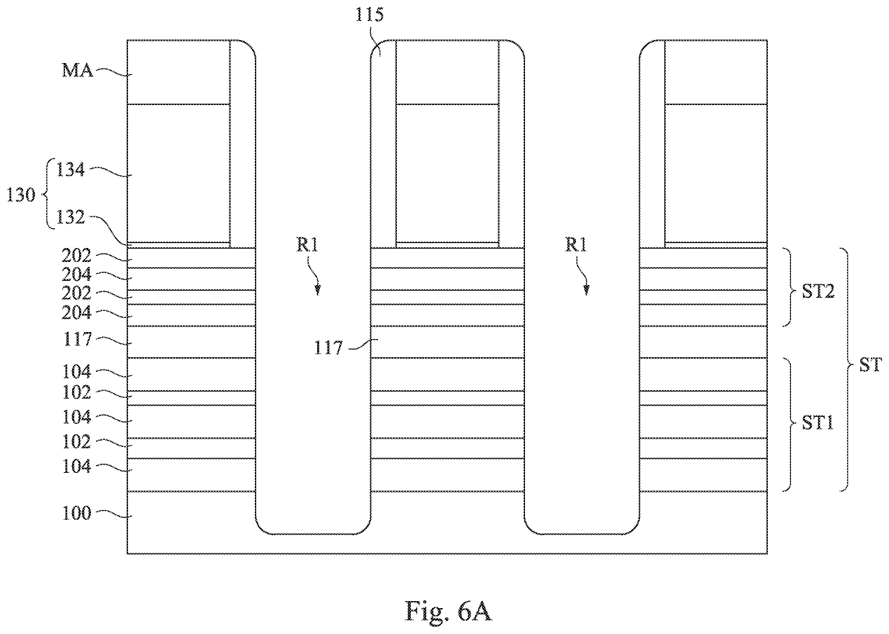

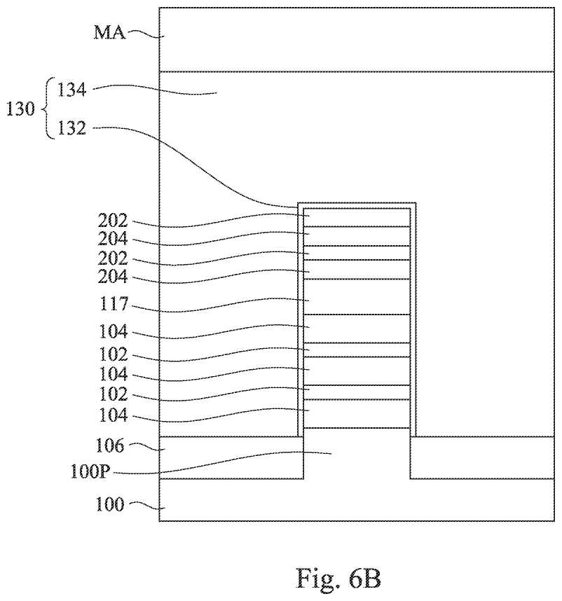

In FIGS. 6A and 6B, isolation structures 117 are formed between the topmost semiconductor layer 104 and the bottommost semiconductor layer 202. In some embodiments, the isolation structures 117 are formed by, for example, depositing a dielectric layer over the substrate 110 until the gaps G1 between the bottom stack ST1 and the top stack are overfilled, followed by removing excess portions of the dielectric layer out of the gaps G1 by using an anisotropic etching process, while leaving portions of the dielectric layer in the gaps G1 to serve as isolation structures 117 separating the bottom stack ST1 from the top stack ST2. In some embodiments, the isolation layer may be deposited by a conformal deposition process, such as CVD, ALD, or the like. The dielectric layer may include a material such as SiN, SiOCN, SiCN, SIOC, although any suitable material, such as low-dielectric constant (low-k) materials having a k-value less than about 3.5, may be utilized.

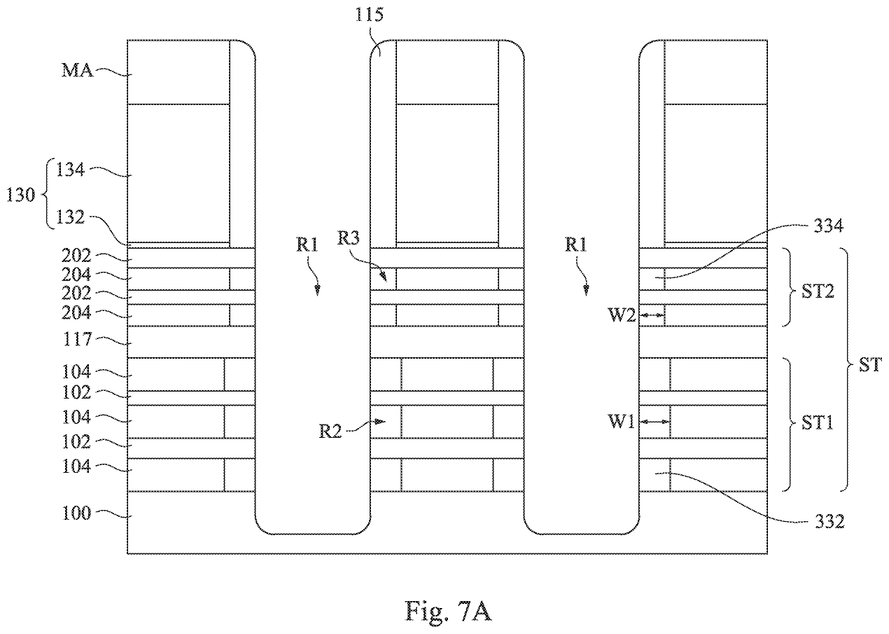

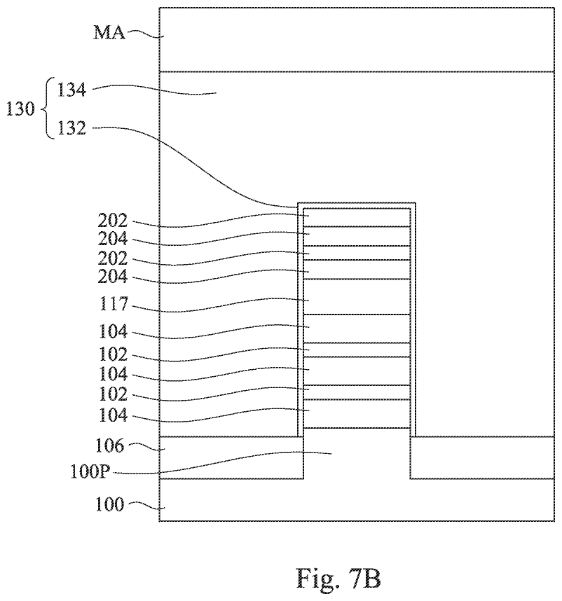

In FIGS. 7A and 7B, portions of sidewalls of the sacrificial semiconductor layers 104 and 204 exposed by the source/drain recesses R1 are etched to form sidewall recesses R2 between corresponding semiconductor layers 102 and sidewall recesses R3 between corresponding semiconductor layers 202. Afterwards, bottom inner spacers 332 are formed in the sidewall recesses R2 in the bottom stack ST1 below the isolation structures 117, and top inner spacers 334 are formed in the sidewall recesses R3 in the top stack ST2 above the isolation structures 117. The inner spacers 332 and 334 act as isolation features between subsequently formed source/drain regions and gate structure. As will be discussed in greater detail below, source/drain regions will be formed in the source/drain recesses R1, and the sacrificial semiconductor layers 104 and 204 will be replaced with corresponding gate structures. In some embodiments, the inner spacers 332 and 334 can be formed by, for example, depositing an inner spacer layer in the sidewall recesses in the bottom stack ST1 and the top stack ST2, followed by etching the inner spacer layer using, for example, an anisotropic etching process, such as RIE, NBE, or the like. Moreover, although the outer sidewalls of the inner spacers 332 and 334 are illustrated as being straight in FIG. 7A, the outer sidewalls of the inner spacers 332 and 334 may be concave or convex.

In some embodiments, the sidewall recesses R2 and R3 are formed in the sidewalls of stacks ST1 and ST2 by using a selective etching process that etches the materials of semiconductor layers 104 and 204 (e.g., SiGe) at a faster etch rate than etching the materials of semiconductor layers 102 and 202 (e.g., Si). In some embodiments, because the exposed sidewalls of the semiconductor layers 104 in the bottom stack ST1 are larger than the exposed sidewalls of the semiconductor layers 204 in the top stack ST2, the etch amount of the semiconductor layers 104 may be greater than the etch amount of the semiconductor layers 204, which in turn leads to the sidewall recesses R2 in bottom stack ST1 having a larger width than the sidewall recesses R2 in the top stack ST2, which in turn leads to the bottom inner spacers 332 having a width W1 greater than a width W2 of the top inner spacers 334. In some embodiments, the ratio of the width W1 to the width W2 depends on the thickness ratio of the semiconductor layer 104 to the semiconductor layer 204. In particular, the ratio of the width W1 to the width W2 is in positive correlation with the thickness ratio of the semiconductor layer 104 to the semiconductor layer 204.

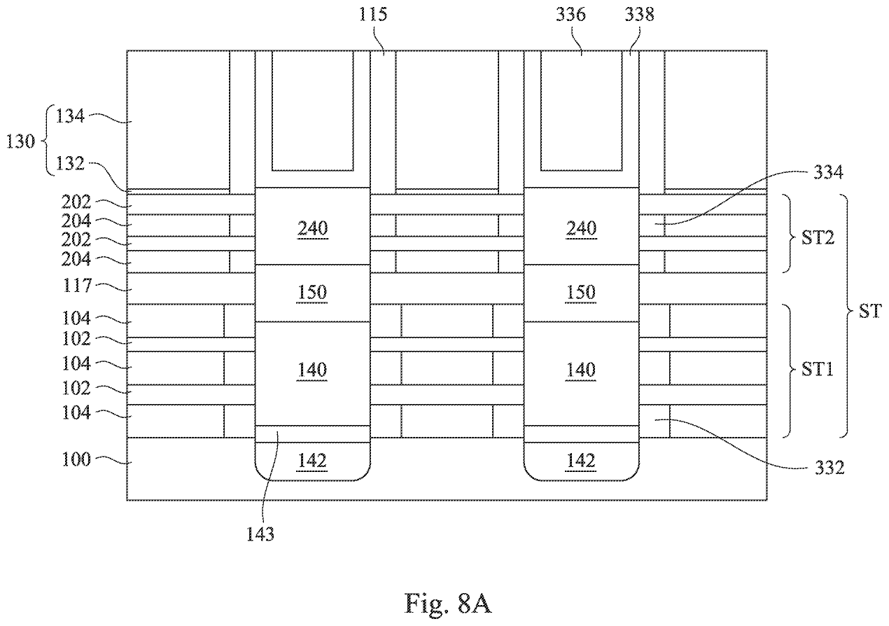

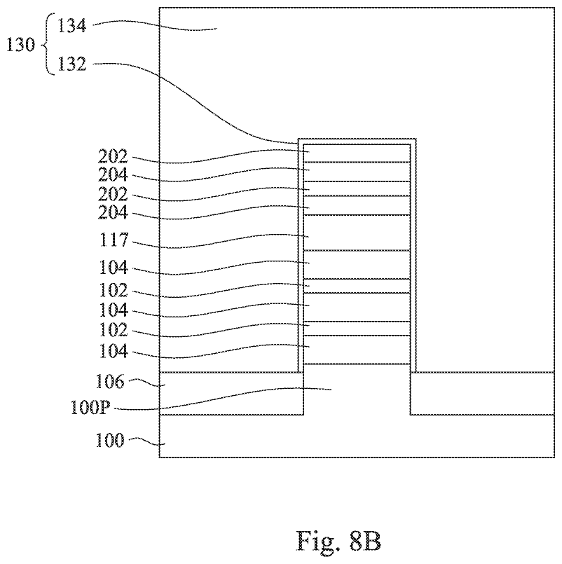

In FIGS. 8A and 8B, Epitaxy layers 142 are formed at bottoms of the source/drain recesses R1. In some embodiments, the formation of the epitaxy layers 142 may include a plurality of deposition-etching cycles, wherein each cycle may include a selective epitaxial growth (SEG) deposition step, followed by an etching step. In some embodiments, the epitaxy layers 142 are un-doped, such as un-doped silicon. After forming the epitaxial layers 142, dielectric layers 143 are formed over the epitaxial layers 142. In some embodiments, the dielectric layers 143 may be formed by depositing a dielectric material in the source/drain recesses R1 and then etching back the dielectric material. In some embodiments, the dielectric layers 143 are made of silicon nitride (SiN), which serves to reduce current leakage from bottom epitaxial source/drain regions 140 to the substrate 100.

After forming the dielectric layers 143, bottom epitaxial source/drain regions 140 are formed in the source/drain recesses R1. In some embodiments, the bottom source/drain regions 140 may exert stress on the second semiconductor layers 102, thereby improving device performance. As illustrated in FIG. 8A, the bottom epitaxial source/drain regions 140 are formed in the source/drain recesses R1 such that each dummy gate structures 130 is disposed between respective neighboring pairs of the bottom epitaxial source/drain regions 140. In some embodiments, the bottom inner spacers 332 are used to separate the bottom epitaxial source/drain regions 140 from the first semiconductor layers 104 by an appropriate lateral distance so that the bottom epitaxial source/drain regions 140 do not short out with subsequently formed gates of the resulting bottom GAA-FETs.

In some embodiments, the bottom epitaxial source/drain regions 140 may include any acceptable material appropriate for p-type GAA-FETs. For example, if the second semiconductor layers 102 are silicon, the bottom epitaxial source/drain regions 140 may comprise materials exerting a compressive strain on the second semiconductor layers 102, such as silicon germanium, boron doped silicon germanium, germanium, germanium tin, or the like. In some embodiments, the bottom epitaxial source/drain regions 140 may include any acceptable material appropriate for n-type GAA-FETs. For example, if the second semiconductor layers 102 are silicon, the bottom epitaxial source/drain regions 140 may include materials exerting a tensile strain on the second semiconductor layers 102, such as silicon carbide, phosphorous doped silicon carbide, silicon phosphide, or the like.

The bottom epitaxial source/drain regions 140 may be implanted with dopants to form source/drain regions, followed by an anneal process. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the bottom epitaxial source/drain regions 140 may be in situ doped during growth. In some embodiments where the bottom epitaxial source/drain regions 140 are doped with an n-type dopant (e.g., phosphorus, arsenic, antimony), the bottom GAA-FETs can serve as n-type transistors. In some embodiments where the bottom epitaxial source/drain regions 140 are doped with a p-type dopant (e.g., boron), the bottom GAA-FETs can serve as p-type transistors.

The bottom epitaxial source/drain regions 140 are localized to a lower portion of the source/drain recesses R1 below the isolation structures 117, so that the bottom epitaxial source/drain regions 140 will not short out with the channels (i.e., second semiconductor layers 202) of top GAA-FETs. In some embodiments, the bottom epitaxial source/drain regions 140 may be formed by a plurality of deposition-etching cycle, with each cycle including a deposition step followed by an etching step, until the resultant source/drain regions 140 have top surfaces lower than the bottom surfaces of the isolation structures 117. In some embodiments, the bottom epitaxial source/drain regions 140 may be formed by masking end surfaces of the second semiconductor layers 202 using a mask layer, while leaving end surfaces of the second semiconductor layers 102 exposed, followed by growing the bottom epitaxial source/drain regions 140 from the exposed end surfaces of the second semiconductor layers 102 by using selective epitaxial growth, followed by removing the mask layer.

After forming the bottom epitaxial source/drain regions 140, isolation structures 150 are formed over the epitaxial source/drain regions 140, respectively. The isolation structures 150 may be formed by, for example, depositing dielectric material(s) over the bottom epitaxial source/drain regions 140, followed by etching back the dielectric material(s). In some embodiments, the isolation structures 150 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide.

Once formation of the isolation structures 150 is completed, top epitaxial source/drain regions 240 are formed in the source/drain recesses R1. In some embodiments, the source/drain regions 240 may exert stress on the second semiconductor layers 202, thereby improving the device performance of top GAA-FETs. As illustrated in FIG. 8A, the epitaxial source/drain regions 240 are formed in the source/drain recesses R1 such that each dummy gate structure 130 is disposed between respective neighboring pairs of the epitaxial source/drain regions 240. In some embodiments, the gate spacers 115 are used to separate the epitaxial source/drain regions 240 from the dummy gate structures 130, and the top inner spacers 334 are used to separate the top epitaxial source/drain regions 240 from the first semiconductor layers 202 by an appropriate lateral distance so that the top epitaxial source/drain regions 240 do not short out with subsequently formed gates of the resulting top GAA-FETs.

In some embodiments, the top epitaxial source/drain regions 240 may include any acceptable material appropriate for n-type GAA-FETs. For example, if the second semiconductor layers 202 are silicon, the top epitaxial source/drain regions 240 may include materials exerting a tensile strain on the second semiconductor layers 202, such as silicon carbide, phosphorous doped silicon carbide, silicon phosphide, or the like. In some embodiments, the top epitaxial source/drain regions 240 may include any acceptable material appropriate for p-type GAA-FETs. For example, if the second semiconductor layers 202 are silicon, the top epitaxial source/drain regions 240 may comprise materials exerting a compressive strain on the second semiconductor layers 202, such as silicon germanium, boron doped silicon germanium, germanium, germanium tin, or the like.

The top epitaxial source/drain regions 240 may be implanted with dopants to form source/drain regions, followed by an anneal process. The source/drain regions may have an impurity concentration of between about 1×10¹⁷ atoms/cm³ and about 1×10²² atoms/cm³. The n-type and/or p-type impurities for source/drain regions may be any of the impurities previously discussed. In some embodiments, the top epitaxial source/drain regions 240 may be in situ doped during growth. In some embodiments where the top epitaxial source/drain regions 240 are doped with an n-type dopant (e.g., phosphorus, arsenic, antimony), the top GAA-FETs can serve as n-type transistors. In some embodiments where the top epitaxial source/drain regions 240 are doped with a p-type dopant (e.g., boron), the top GAA-FETs can serve as p-type transistors. In some embodiments, the top epitaxial source/drain regions 240 are of a conductivity type different from a conductivity type of the bottom epitaxial source/drain regions 140, and thus the top GAA-FETs are of a conductivity type different from a conductivity type of the bottom GAA-FETs, which enables the formation of a CFET structure.

After forming the top epitaxial source/drain regions 240, an interlayer dielectric (ILD) layer 336 is deposited over the top epitaxial source/drain regions 240 and the dummy gate structures 130. The ILD layer 336 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 338 is disposed between the ILD layer 336 and the top epitaxial source/drain regions 240. The CESL 338 may comprise a dielectric material, such as, SiN, SiOₓ, SiCN, SiON, SiOCN, Al₂O₃, HfO₂, ZrO₂, HfAlOₓ, and HfSiOₓ, or the like, having a different etch rate than the material of the overlying ILD layer 336.

Afterwards, a planarization process, such as a CMP, may be performed to level the top surface of the ILD layer 336 with the top surfaces of the dummy gate structures 130. The planarization process may also remove the patterned masks MA on the dummy gate structures 130, and portions of the gate spacers 115 along sidewalls of the patterned masks MA. After the planarization process, top surfaces of the dummy gate structures 130, the gate spacers 115, and the ILD layer 336 are level within process variations. Accordingly, the top surfaces of the dummy gate structures 130 are exposed through the ILD layer 336. In some embodiments, the patterned masks MA may remain, in which case the planarization process levels the top surface of the ILD layer 336 with top surface of the patterned masks MA and the gate spacers 115.

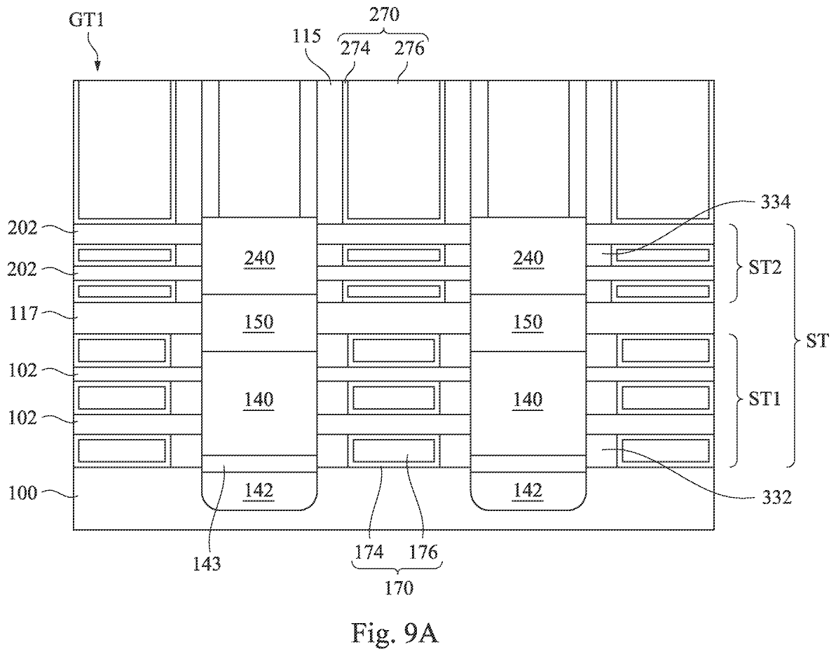

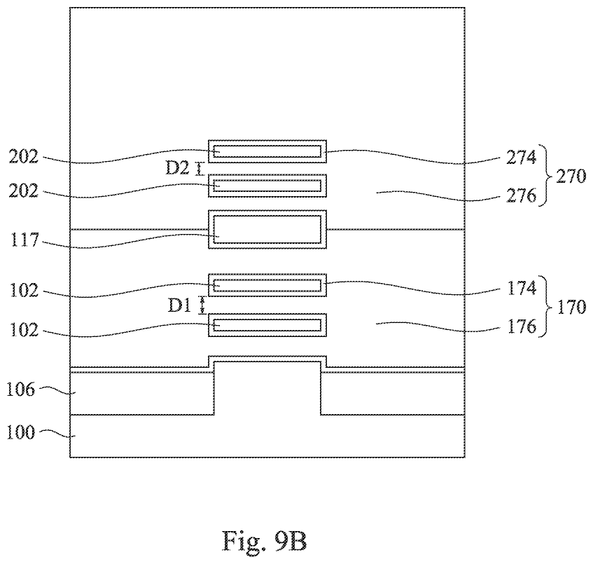

In FIGS. 9A and 9B, the dummy gate structures 130, and the patterned masks MA if present, are removed in one or more etching steps, so that gate trenches GT1 are formed between corresponding gate spacers 115. In some embodiments, the dummy gate structures 130 are removed by an anisotropic dry etch process. For example, the etching process may include a dry etch process using reaction gas(es) that selectively etch the dummy gate structures 130 at a faster rate than the gate spacers 115. Each gate trench GT1 exposes and/or overlies portions of second semiconductor layers 102, 202, which will serve as channel regions in subsequently completed GAA-FETs. The second semiconductor layers 102 serving as channel regions are disposed between neighboring pairs of the bottom epitaxial source/drain regions 140. The second semiconductor layers 202 serving as channel regions are disposed between neighboring pairs of the top epitaxial source/drain regions 240.

Afterwards, the first semiconductor layers 104 and 204 exposed in the gate trenches GT1 are removed by an isotropic etching process such as wet etching or the like using etchants which are selective to the materials of the first semiconductor layers 104 and 204. Stated differently, the first semiconductor layers 104 and 204 are removed by using a selective etching process that etches the first semiconductor layers 104 and 204 at a faster etch rate than it etches the second semiconductor layers 102 and 202, thus forming spaces between corresponding two of the second semiconductor layers 102 and 202 (also referred to as sheet-to-sheet spaces, because the second semiconductor layers 102 and 202 are also called nanosheets). This step can be referred to as a channel release process. At this interim processing step, the spaces between second semiconductor layers 102 and 202 may be filled with ambient environment conditions (e.g., air, nitrogen, etc). In some embodiments, the second semiconductor layers 102 and 202 can be referred to as nanosheets, nanowires, nanoslabs, nanorings having nano-scale size (e.g., a few nanometers), depending on their geometry. For example, in some embodiments the second semiconductor layers 102 and 202 may be trimmed to have a substantial rounded shape (i.e., cylindrical) due to the selective etching process for completely removing the first semiconductor layers 104 and 204. In that case, the resultant second semiconductor layers 102 and 202 can be called nanowires. In embodiments in which the first semiconductor layers 104 and 204 include, e.g., SiGe, and the second semiconductor layers 102 and 202 include, e.g., Si or SiC, tetramethylammonium hydroxide (TMAH), ammonium hydroxide (NH₄OH) or the like may be used to remove the first semiconductor layers 104 and 204.

After the channel release process, gate dielectric layers 174 and 274 are formed wrapping around the second semiconductor layers 102 and 202, respectively. In some embodiments, the gate dielectric layers 174 and 274 may be formed using a same deposition process. In some embodiments, interfacial layers (not shown) may be formed over the semiconductor layers 102 and 202 prior to forming the gate dielectric layers 174 and 274. In the cross-sectional view of FIG. 8B, a dielectric layer made of a same material as the gate dielectric layers 174 and 274 may wrap around the isolation structures 117.

Then, gate electrodes 176 are formed over the gate dielectric layers 174. The gate electrodes 176 are then etched back, such that the remaining gate electrodes 176 are localized to the lower portions of the gate trenches GT1 below the top surface of the isolation structures 117, which in turn forms bottom gate structures 170 at the lower portions of gate trenches GT1. In greater detail, the bottom gate structures 170 are formed in bottom portions of the gate trenches GT1, and each of the bottom gate structures 170 may include gate dielectric layers 174 wrapping around the respective second semiconductor layers 102, and a gate electrode 176 wrapping around the gate dielectric layers 174.

Gate electrodes 276 are formed in the gate trenches GT1 and over the bottom gate structures 170. In greater detail, the top gate structures 270 are formed in upper portions of the gate trenches GT1, and each of the top gate structures 270 may include gate dielectric layers 274 wrapping around the respective second semiconductor layers 202, and a gate electrode 276 wrapping around the gate dielectric layers 274.

In some embodiments, the gate dielectric layers 174 and 274 each include an interfacial layer and a high-k dielectric layer over the interfacial layer. In some embodiments, the interfacial layer is silicon oxide formed on exposed surfaces of semiconductor materials (e.g., Si) in the gate trenches GT1 by using, for example, thermal oxidation, chemical oxidation, wet oxidation or the like. As a result, surface portions of the semiconductor layers 102, 202 exposed in the gate trenches GT1 are oxidized into semiconductor oxide to form interfacial layers. In some embodiments, the high-k dielectric layer has a dielectric constant greater than a dielectric constant of silicon oxide (about 3.9). The high-k gate dielectric layer includes dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof.

The gate electrodes 176 and 276 may include work function metal layer(s) and a filling metal. The work function metal layer may be an n-type or p-type work function layer. Exemplary p-type work function metals include titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. Exemplary n-type work function metals include titanium aluminide (TiAl), titanium aluminium nitride (TiAIN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AIC)), aluminides, and/or other suitable materials. The filling metal may include tungsten (W) or another suitable conductive material(s). In some embodiments, the gate electrodes 176 may include one or more p-type work function metal layers serving for p-type GAA-FETs, while the gate electrodes 276 may include one or more p-type work function metal layers serving for n-type GAA-FETs.

In some embodiments as illustrated in FIG. 9B, the distance D1 between the bottom channel layers 102 is greater than the distance D2 between the top channel layers 202, and thus the bottom GAA-FETs have larger sheet-to-sheet spaces than the top GAA-FETs, which in turn allows for the bottom gate electrode 176 having more work function metal layers than the top gate electrode 276. By way of example and not limitation, in some embodiments where the CFET structure includes an NFET stacked on a PFET, a number of p-type work function metal layers (e.g., TiN) of the bottom gate electrode 176 may be greater than a number of p-type work function metal layers (e.g., TiN) of the top gate electrode 276, allowing the bottom gate electrode 176 more suitable for serving as a PFET gate. In some other embodiments where the CFET structure includes a PFET stacked on an NFET, a number of n-type work function metal layers (e.g., Al) of the bottom gate electrode 176 may be greater than a number of n-type work function metal layers (e.g., Al) of the top gate electrode 276, allowing the bottom gate electrode 176 more suitable for serving as an NFET gate.

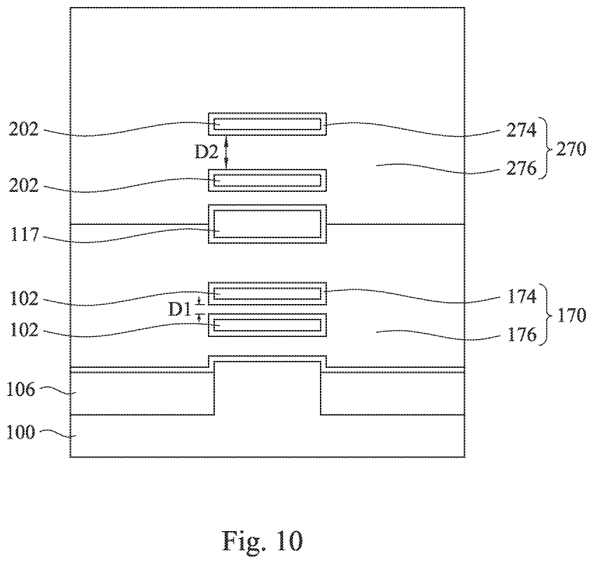

FIG. 10 illustrates a cross-sectional view of a CFET structure in accordance with some embodiments of the present disclosure. The structure as illustrated in FIG. 10 is similar to that of FIG. 9B, except that the distance D1 between the bottom channel layers 102 is less than the distance D2 between the top channel layers 202, and thus the top GAA-FETs have larger sheet-to-sheet spaces than the bottom GAA-FETs, which in turn allows for the top gate electrode 276 having more work function metal layers than the bottom gate electrode 276. By way of example and not limitation, in some embodiments where the CFET structure includes a PFET stacked on an NFET, a number of p-type work function metal layers (e.g., TiN) of the top gate electrode 276 may be greater than a number of p-type work function metal layers (e.g., TiN) of the bottom gate electrode 176, allowing the top gate electrode 276 more suitable for serving as a PFET gate. In some embodiments, where the CFET structure includes an NFET stacked on a PFET, a number of n-type work function metal layers (e.g., Al) of the top gate electrode 276 may be greater than a number of n-type work function metal layers (e.g., Al) of the bottom gate electrode 176, allowing the top gate electrode 276 more suitable for serving as an NFET gate.

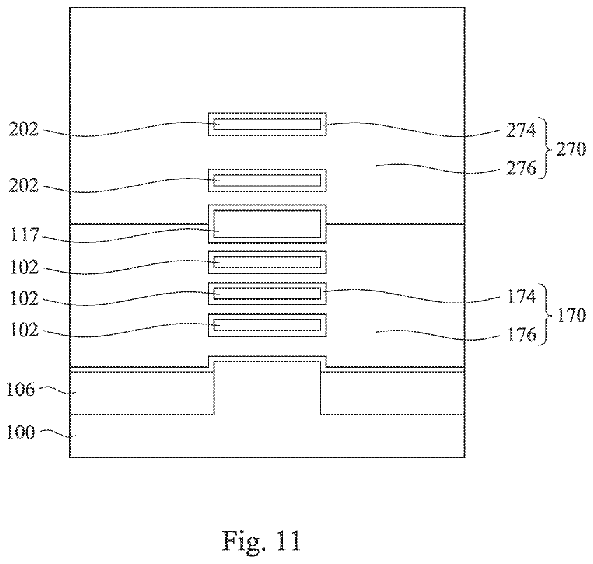

FIG. 11 illustrates a cross-sectional view of a CFET structure in accordance with some embodiments of the present disclosure. The structure as illustrated in FIG. 11 is similar to that of FIG. 10, except that a number of bottom channel layers 102 is greater than a number of top channel layers 202, which allows for the bottom GAA-FETs having an on-current than an on-current of top GAA-FETs.

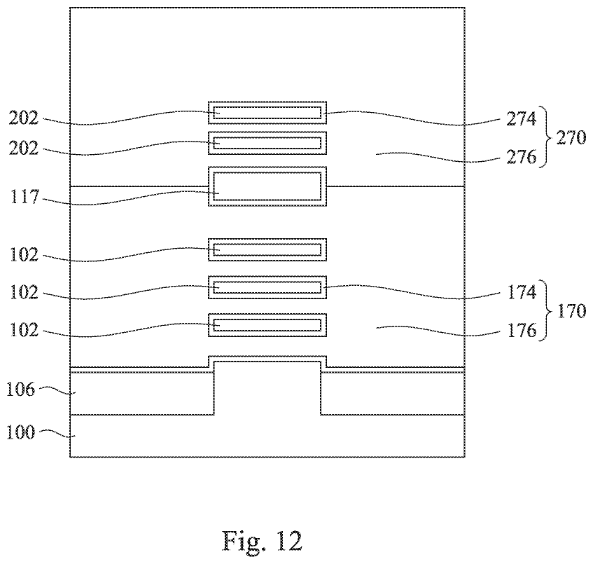

FIG. 12 illustrates a cross-sectional view of a CFET structure in accordance with some embodiments of the present disclosure. The structure as illustrated in FIG. 12 is similar to that of FIG. 11, except that the bottom GAA-FETs have larger sheet-to-sheet spaces than the top GAA-FETs, which in turn allows for the bottom gate electrode 176 having more work function metal layers than the top gate electrode 276.

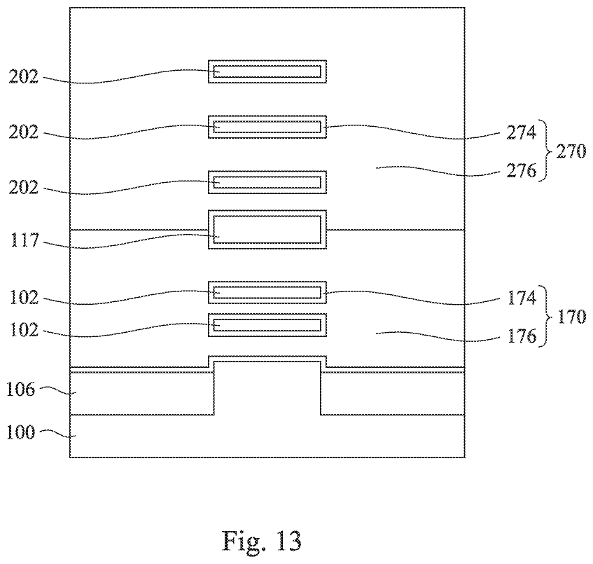

FIG. 13 illustrates a cross-sectional view of a CFET structure in accordance with some embodiments of the present disclosure. The structure as illustrated in FIG. 13 is similar to that of FIG. 11, except that a number of top channel layers 202 is greater than a number of bottom channel layers 202, which allows for the top GAA-FETs having an on-current than an on-current of bottom GAA-FETs.

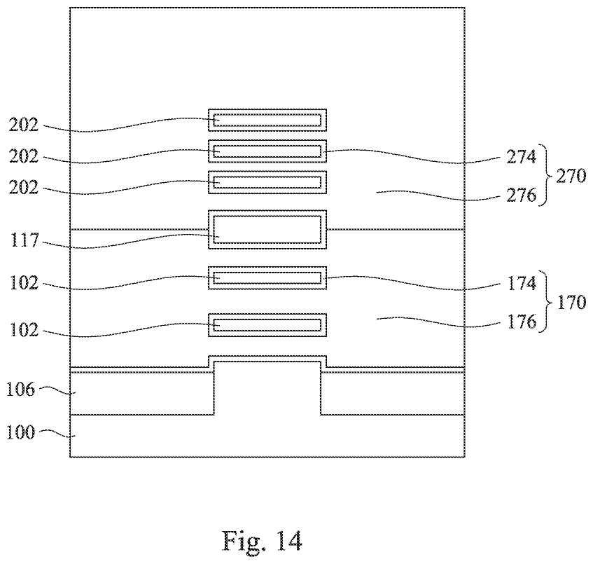

FIG. 14 illustrates a cross-sectional view of a CFET structure in accordance with some embodiments of the present disclosure. The structure as illustrated in FIG. 14 is similar to that of FIG. 13, except that the bottom GAA-FETs have larger sheet-to-sheet spaces than the top GAA-FETs, which in turn allows for the bottom gate electrode 176 having more work function metal layers than the top gate electrode 276.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the NFET and PFET have varied spacing between their sheets, which in turn improves the device's capability for better metal gate work function metal (MG WFM) tuning and more precise threshold voltage (Vt) control.

In some embodiments, a method comprises forming a first stack of alternating first semiconductor layers and second semiconductor layers over a substrate; forming a sacrificial semiconductor layer over the first stack; forming a second stack of alternating third semiconductor layers and fourth semiconductor layers over the sacrificial semiconductor layer, wherein one or more of the first semiconductor layers have a thickness different from a thickness of one or more of the third semiconductor layers; replacing the sacrificial semiconductor layer with an isolation structure; replacing the first semiconductor layers with a first gate structure; and replacing the third semiconductor layers with a second gate structure. In some embodiments, a distance between the second semiconductor layers is different from a distance between the fourth semiconductor layers. In some embodiments, a distance between the second semiconductor layers is greater than a distance between the fourth semiconductor layers. In some embodiments, a distance between the second semiconductor layers is less than a distance between the fourth semiconductor layers. In some embodiments, a number of the second semiconductor layers is different from a number of the fourth semiconductor layers. In some embodiments, a number of the second semiconductor layers is greater than a number of the fourth semiconductor layers. In some embodiments, a number of the second semiconductor layers is less than a number of the fourth semiconductor layers. In some embodiments, the method further comprises laterally etching the first semiconductor layers and the third semiconductor layers; forming first inner spacers on opposite sides of the laterally etched first semiconductor layers; and forming second inner spacers on opposite sides of the laterally etched third semiconductor layers, wherein one or more of the first inner spacers have a width different from a width of one or more of the second inner spacers. In some embodiments, the width of the one or more of the first inner spacers is greater than the width of the one or more of the second inner spacers.

In some embodiments, a method comprises forming a multilayer stack over a substrate, the multilayer stack comprising a first stack, a sacrificial layer over the first stack, and a second stack over the first stack, wherein the first stack comprises first channel layers, the second stack comprises second channel layers, and a distance between the first channel layers is different from a distance between the second channel layers; etching source/drain recesses in the multilayer stack; replacing the sacrificial layer with an isolation layer; forming first epitaxial source/drain regions in lower portions of the source/drain recesses; forming isolation structures over the first epitaxial source/drain regions; forming second epitaxial source/drain regions over the isolation structures; forming a first gate structure wrapping around the first channel layers; and forming a second gate structure wrapping around the second channel layers. In some embodiments, the distance between the first channel layers is greater than the distance between the second channel layers. In some embodiments, the distance between the first channel layers is less than the distance between the second channel layers. In some embodiments, a number of the first channel layers is different from a number of the second channel layers. In some embodiments, a number of the first channel layers is greater than a number of the second channel layers. In some embodiments, a number of the first channel layers is less than a number of the second channel layers. In some embodiments, the first epitaxial source/drain regions are of a conductivity type different from a conductivity type of the second epitaxial source/drain regions.

In some embodiments, a device comprises a first transistor and a second transistor over the first transistor. The first transistor comprises a plurality of first channel layers arranged one above another, a first gate structure wrapping around each of the plurality of first channel layers, and first source/drain regions on opposite sides of the first gate structure. The second transistor comprises a plurality of second channel layers arranged one above another, a second gate structure wrapping around each of the plurality of second channel layers, and second source/drain regions on opposite sides of the second gate structure. A distance between the plurality of first channel layers is different from a distance between the plurality of second channel layers. In some embodiments, the device further comprises a plurality of first inner spacers spacing the first gate structure apart from the first source/drain regions, and a plurality of second inner spacers spacing the second gate structure apart from the second source/drain regions. One or more of the plurality of first inner spacers has a width different from a width of one or more of the plurality of second inner spacers. In some embodiments, the width of the one or more of the plurality of first inner spacers is greater than the width of the one or more of the plurality of second inner spacers. In some embodiments, the device further comprises an isolation structure having a top surface in contact with one of the second source/drain regions, and a bottom surface in contact with one of the first source/drain regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first stack of alternating first semiconductor layers and second semiconductor layers over a substrate;
forming a sacrificial semiconductor layer over the first stack;
forming a second stack of alternating third semiconductor layers and fourth semiconductor layers over the sacrificial semiconductor layer, wherein one or more of the first semiconductor layers have a thickness different from a thickness of one or more of the third semiconductor layers;
replacing the sacrificial semiconductor layer with an isolation structure;
replacing the first semiconductor layers with a first gate structure; and
replacing the third semiconductor layers with a second gate structure.

2. The method of claim 1, wherein a distance between the second semiconductor layers is different from a distance between the fourth semiconductor layers.

3. The method of claim 1, wherein a distance between the second semiconductor layers is greater than a distance between the fourth semiconductor layers.

4. The method of claim 1, wherein a distance between the second semiconductor layers is less than a distance between the fourth semiconductor layers.

5. The method of claim 1, wherein a number of the second semiconductor layers is different from a number of the fourth semiconductor layers.

6. The method of claim 1, wherein a number of the second semiconductor layers is greater than a number of the fourth semiconductor layers.

7. The method of claim 1, wherein a number of the second semiconductor layers is less than a number of the fourth semiconductor layers.

8. The method of claim 1, further comprising:
laterally etching the first semiconductor layers and the third semiconductor layers;
forming first inner spacers on opposite sides of the laterally etched first semiconductor layers; and
forming second inner spacers on opposite sides of the laterally etched third semiconductor layers, wherein one or more of the first inner spacers have a width different from a width of one or more of the second inner spacers.

9. The method of claim 8, wherein the width of the one or more of the first inner spacers is greater than the width of the one or more of the second inner spacers.

10. A method comprising:
forming a multilayer stack over a substrate, the multilayer stack comprising a first stack, a sacrificial layer over the first stack, and a second stack over the first stack, wherein the first stack comprises first channel layers, the second stack comprises second channel layers, and a distance between the first channel layers is different from a distance between the second channel layers;
etching source/drain recesses in the multilayer stack;
replacing the sacrificial layer with an isolation layer;
forming first epitaxial source/drain regions in lower portions of the source/drain recesses;
forming isolation structures over the first epitaxial source/drain regions;
forming second epitaxial source/drain regions over the isolation structures;
forming a first gate structure wrapping around the first channel layers; and
forming a second gate structure wrapping around the second channel layers.

11. The method of claim 10, wherein the distance between the first channel layers is greater than the distance between the second channel layers.

12. The method of claim 10, wherein the distance between the first channel layers is less than the distance between the second channel layers.

13. The method of claim 10, wherein a number of the first channel layers is different from a number of the second channel layers.

14. The method of claim 10, wherein a number of the first channel layers is greater than a number of the second channel layers.

15. The method of claim 10, wherein a number of the first channel layers is less than a number of the second channel layers.

16. The method of claim 10, wherein the first epitaxial source/drain regions are of a conductivity type different from a conductivity type of the second epitaxial source/drain regions.

17. A device comprising:
a first transistor comprising a plurality of first channel layers arranged one above another, a first gate structure wrapping around each of the plurality of first channel layers, and first source/drain regions on opposite sides of the first gate structure; and
a second transistor over the first transistor, the second transistor comprising a plurality of second channel layers arranged one above another, a second gate structure wrapping around each of the plurality of second channel layers, and second source/drain regions on opposite sides of the second gate structure,
wherein a distance between the plurality of first channel layers is different from a distance between the plurality of second channel layer.

18. The device of claim 17, further comprising:
a plurality of first inner spacers spacing the first gate structure apart from the first source/drain regions; and
a plurality of second inner spacers spacing the second gate structure apart from the second source/drain regions, wherein one or more of the plurality of first inner spacers has a width different from a width of one or more of the plurality of second inner spacers.

19. The device of claim 18, wherein the width of the one or more of the plurality of first inner spacers is greater than the width of the one or more of the plurality of second inner spacers.

20. The device of claim 17, further comprising:
an isolation structure having a top surface in contact with one of the second source/drain regions, and a bottom surface in contact with one of the first source/drain regions.
